(19) United States
(12) Patent Application Publication
(10) Pub. No.: US 2016/0126087 A1
(43) Pub. Date: May 5, 2016

(54) METHOD OF MANUFACTURING SEMICONDUCTOR DEVICE

(71) Applicant: Kabushiki Kaisha Toshiba, Minato-ku (JP)

(72) Inventors: Kazumasa TANIDA, Yokohama (JP); Hiroaki Ashidate, Oita (JP)

(73) Assignee: Kabushiki Kaisha Toshiba, Minato-ku (JP)

(21) Appl. No.: 14/848,855

(22) Filed: Sep. 9, 2015

(30) Foreign Application Priority Data
Nov. 4, 2014 (JP) 2014-224491

(51) Int. Cl. H01L 21/02; H01L 27/146

(52) U.S. Cl. CPC H01L 21/02068; H01L 27/14687; H01L 27/1469; H01L 27/14636

(57) ABSTRACT

A method of manufacturing a semiconductor device according to an embodiment includes forming an opening in a surface of an insulating layer which is provided in a surface of a first substrate and a surface of a second substrate. The method includes filling the opening with metal. The method includes activating the surface of the insulating layer. The method includes cleaning the surface of the metal filled in the opening of the first substrate using carbonated water. The method includes connecting the filled metal of the first substrate and the filled metal of the second substrate by bonding the insulating layer of the first substrate and the insulating layer of the second substrate.

### CROSS-REFERENCE TO RELATED APPLICATIONS

This application is based upon and claims the benefit of priority from Japanese Patent Application No. 2014-224491, filed on Nov. 4, 2014; the entire contents of which are incorporated herein by reference.

### FIELD

Embodiments described herein relate generally to a method of manufacturing a semiconductor device.

### BACKGROUND

Conventionally, there is a semiconductor device which can be reduced in occupancy area by stacking semiconductor chips in multi stages. The semiconductor device is, for example, manufactured by bonding substrates in multi stages in which semiconductor elements and integrated circuits are formed, and by dicing the substrates in a unit of semiconductor chip.

An insulating layer is provided in the surface of each substrate to be bonded, and a plurality of electrodes are provided at positions corresponding to the surfaces of the respective insulating layers by bonding the substrates. However, there may be formed a metal oxide film in the surface of the electrode due to natural oxidation. In such a case, when the substrates are bonded to each other, a bonding failure may occur in a bonding portion between the electrodes.

### BRIEF DESCRIPTION OF THE DRAWINGS

FIGS. 1A to 2C are diagrams for describing a forming procedure of an electrode according to an embodiment;

FIGS. 3A and 3B are diagrams for describing an activating procedure according to an embodiment;

FIG. 4 is a diagram for describing a cleaning apparatus according to an embodiment;

FIG. 5 is a Pourbaix diagram of copper;

FIGS. 6A and 6B are diagrams for describing a cleaning procedure according to an embodiment;

FIGS. 7A to 7D are diagrams for describing a bonding procedure of a substrate according to an embodiment; and

FIGS. 8A to 9B are diagrams for describing a method of direct bonding of the substrate according to an embodiment.

### DETAILED DESCRIPTION

According to this embodiment, there is provided a method of manufacturing a semiconductor device. The method of manufacturing the semiconductor device includes forming an opening in a surface of an insulating layer that is provided in each surface of a first substrate and a second substrate. The method includes filling the opening with metal. The method includes activating the surface of the insulating layer. The method includes cleaning a surface of the metal filled in the opening of the first substrate using carbonated water. The method includes connecting the filled metal of the first substrate and the filled metal of the second substrate by bonding the insulating layer of the first substrate and the insulating layer of the second substrate.

The method of manufacturing the semiconductor device according to an embodiment will be described with reference to the accompanying drawings. Further, the present invention is not limited by the embodiment. In the following, the description will be made about an example of a so-called Wafer on Wafer in which the first substrate formed with a logic circuit and the second substrate formed with an image sensor are bonded. However, the method of manufacturing the semiconductor device according to this embodiment can also be employed to Chip on Wafer or Chip on Chip. Further, a circuit formed in the first substrate or the second substrate is not limited to the logic circuit or the image sensor, but may be arbitrary semiconductor integrated circuit.

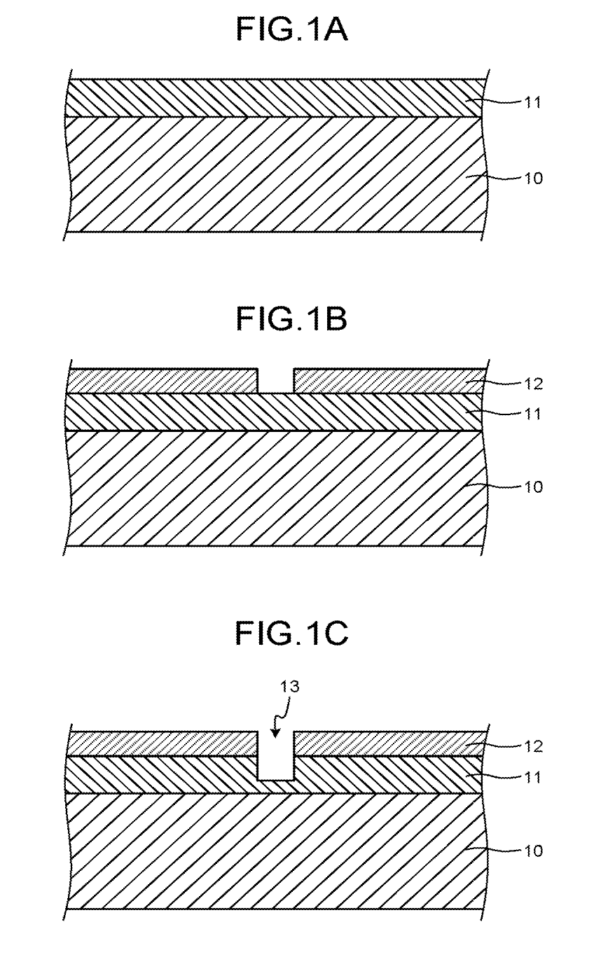

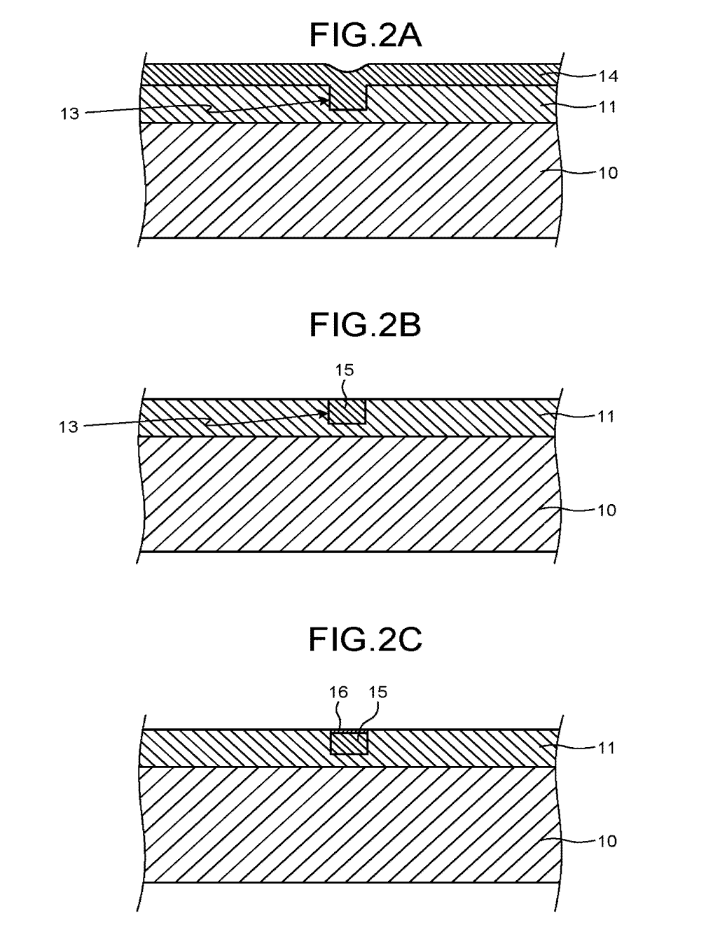

First, a manufacturing procedure of an electrode in the insulating layer provided in the surface of the substrate will be described with reference to FIGS. 1A to 2C. FIGS. 1A to 2C are diagrams for describing a forming procedure of the electrode according to the embodiment. Further, a forming procedure of the electrode in the insulating layer of the first substrate is the same as a forming procedure of the electrode in the insulating layer of the second substrate which is bonded to the first substrate.

Therefore, the description herein will be made about the forming procedure of the electrode in the insulating layer of the first substrate, and a detailed description on the forming procedure of the electrode in the insulating layer of the second substrate will not be given. In FIGS. 1A to 2C, a cross section of a portion near a forming position of the electrode in the first substrate formed with the insulating layer in its surface is schematically illustrated.

As illustrated in FIG. 1A, for example, an insulating layer 11 made of oxide silicon is formed in the surface of a first substrate 10. Herein, the first substrate 10 is, for example, a semiconductor substrate such as a silicon wafer. In the inside of the first substrate 10, a logic circuit (not illustrated) is already formed. In addition, in the inside of the insulating layer 11, wirings connected to the logic circuit are already formed.

In a case where the electrode is formed in the first substrate 10, as illustrated in FIG. 1B, a resist film 12 is coated in the surface of the insulating layer 11, and the resist film 12 is patterned using a photolithography technology, so that the resist film 12 on the position of forming the electrode is selectively removed.

Subsequently, as illustrated in FIG. 1C, for example, an anisotropic etching such as a reactive ion etching (RIE) is performed using the patterned resist film 12 as a mask, so that an opening 13 is formed in the surface of the insulating layer 11. Herein, the opening 13 is formed to have a depth reaching the wiring connected to the logic circuit.

Subsequently, after removing the resist film 12, for example, a barrier metal or a seed metal (not illustrated) is formed by a physical vapor deposition (PVD) in the surface of the insulating layer 11 formed with the opening 13. Then, copper is precipitated by electrolytic plating so as to fill the opening 13, and a metal layer 14 illustrated in FIG. 2A is formed. Further, the metal layer 14 may be formed by a chemical vapor deposition (CVD). In addition, the material of the metal layer 14 may be metal other than the copper.

Thereafter, for example, the surface of the metal layer 14 is polished by chemical mechanical polishing (CMP) to remove the metal layer 14, the barrier metal, or the seed metal (not illustrated) from the surface of the insulating layer 11. Therefore, as illustrated in FIG. 2B, an electrode 15 is formed such that the electrode is buried in the opening 13 and the surface of the electrode becomes flush with the surface of the insulating layer 11. In addition, the electrode is also formed in the second substrate to be boned to the first substrate 10 through the same manufacturing procedure of the first substrate 10.

Until the bonding is performed, the first substrate 10 and the second substrate formed with the electrodes 15 are stored and kept in a sealed vessel called a front opening unified pod (FOUP). Further, in a case where the first substrate 10 and the second substrate are kept, for example, the natural oxidation of the electrode 15 is suppressed by purging an oxidation inhabitation gas such as nitrogen in the FOUP.

However, in a case where the substrate is kept in a long period, or in a case where some time elapses after the first substrate 10 and the second substrate are brought out of the FOUP, as illustrated in FIG. 2C, a metal oxide film 16 is formed in the surface of the electrode 15 due to the natural oxidation. The oxide film 16 causes a bonding failure or an increased bonding resistance between the electrodes in a case where the first substrate 10 and the second substrate are bonded.

As a method of removing the oxide film 16, for example, a wet etching method is generally performed to remove the oxide film 16 using hydrogen fluoride or hydrochloric acid. However, in a case where the wet etching method using hydrogen fluoride is performed, the surface of the insulating layer 11 is roughened, so that a bonding strength between the first substrate 10 and the second substrate may be lowered.

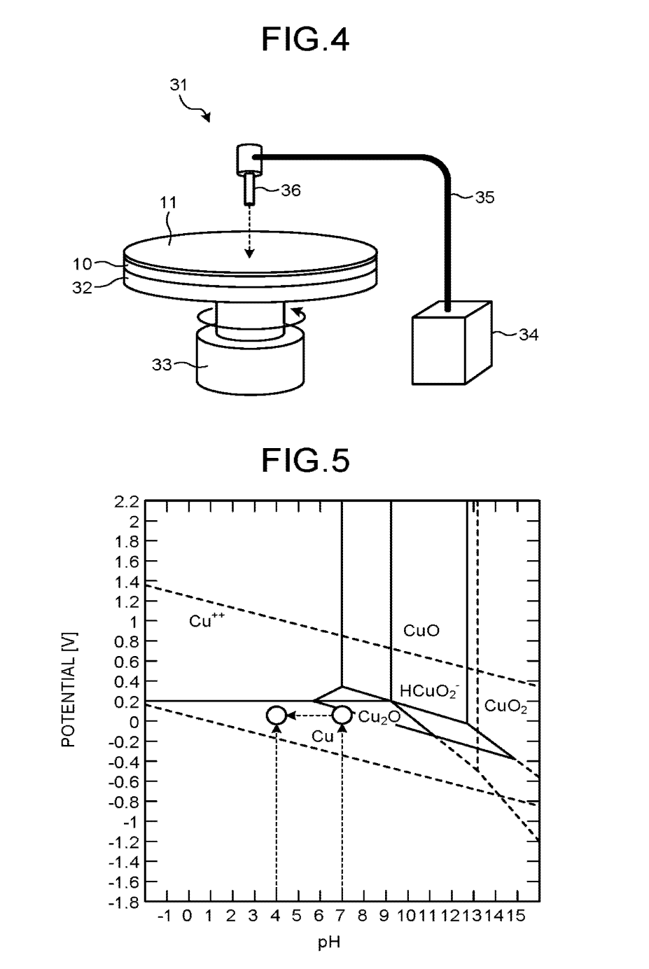

Therefore, in this embodiment, the oxide film 16 is removed from the surface of the electrode 15, while suppressing the surface of the insulating layer 11 from being roughened, by cleaning the surface of the electrode 15 using the carbonated water. In addition, similarly, the oxide film 16 is removed from the surface of the electrode of the second substrate. A cleaning procedure will be described below in detail with reference to FIGS. 4 to 6B.

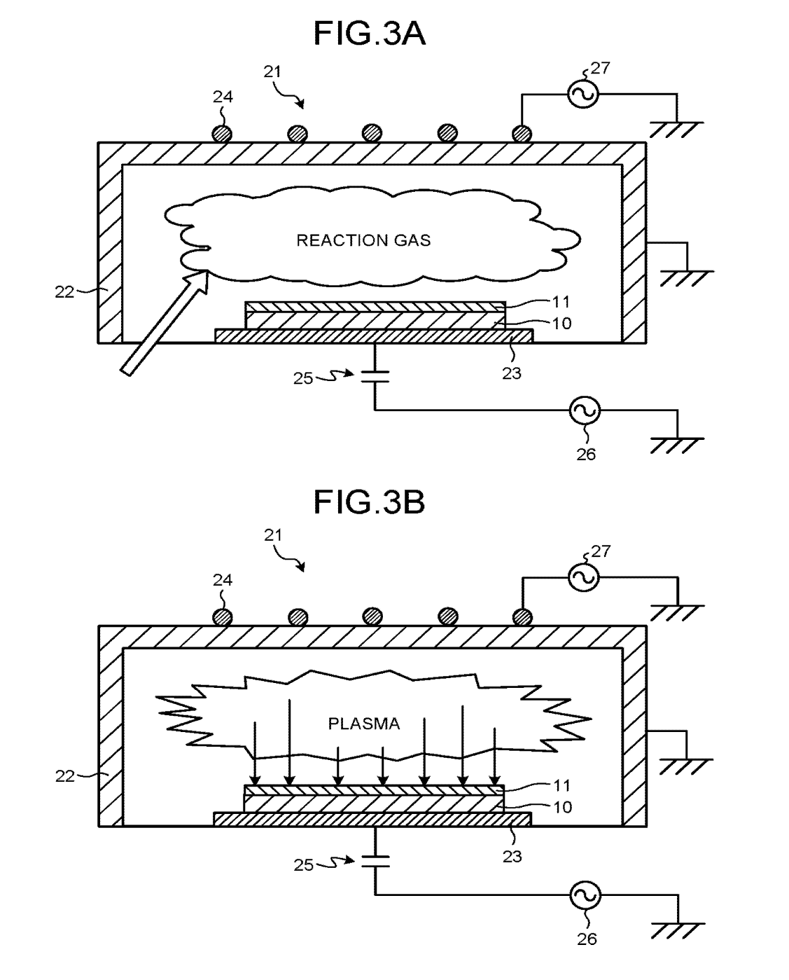

Next, a process of activating the surface of the insulating layer 11 formed with the electrode 15 will be described with reference to FIGS. 3A and 3B. FIGS. 3A and 3B are diagrams for describing an activating procedure according to an embodiment. Herein, an activating procedure of the surface of the insulating layer 11 of the first substrate 10 is the same as an activating procedure of the surface of the insulating layer of the second substrate. Therefore, the description herein will be made only on the activating procedure of the surface of the insulating layer 11 of the first substrate 10, and a detailed description on the process of activating the surface of the insulating layer of the second substrate will not be given.

The process of activating the surface of the insulating layer 11 is performed by an activation apparatus 21 illustrated in FIGS. 3A and 3B. As illustrated in FIGS. 3A and 3B, the activation apparatus 21 includes a chamber 22, a stage 23, an antenna coil 24, a blocking capacitor 25, and radio frequency power sources 26 and 27.

Further, while not illustrated herein, the activation apparatus 21 includes a gas supplying unit which supplies reaction gas into the chamber 22, and a discharge unit which discharges the ambient air in the chamber 22 to the outside of the chamber 22.

The chamber 22 is a treatment chamber where an activation treatment is performed on the surface of the insulating layer 11. The chamber 22 is connected to the ground and provided with the stage 23 therein. The stage 23 is a table on which a target substrate to be placed (herein, the first substrate 10) is adsorbed and attached.

The stage 23 is connected to the ground through the blocking capacitor 25 and the radio frequency power source 26. The antenna coil 24 is a coil which is provided on the tabletop of the chamber 22 and has a spiral shape in plan view. The antenna coil 24 is connected to the ground through the radio frequency power source 27.

In a case where the insulating layer 11 is activated, as illustrated in FIG. 3A, the first substrate 10 is place on the stage 23 in a state where the insulating layer 11 faces upwardly, and the first substrate 10 is adsorbed and attached by the stage 23. Then, the activation apparatus 21 introduces, for example, the nitride reaction gas into the chamber 22.

Thereafter, the activation apparatus 21 applies a radio frequency voltage from the radio frequency power source 27 to the antenna coil 24, and applies a radio frequency voltage from the radio frequency power source 26 to the stage 23 in a state where the inside of the chamber 22 is substantially made vacuous.

Therefore, in the activation apparatus 21, as illustrated in FIG. 3B, the reaction gas in the chamber 22 enters a plasma state. Then, the electrons in the plasma state are attracted toward the ceiling of the chamber 22 facing the antenna coil 24 and the stage 23.

Herein, since the chamber 22 is connected to the ground, the electrons attracted to the ceiling of the chamber 22 flow to the ground. Therefore, the potential of the ceiling of the chamber 22 becomes constant. On the other hand, since the blocking capacitor 25 blocks the DC current, the attracted electrons are accumulated to make the upper electrode charged negatively.

Therefore, the positive ions in the plasma state are attracted toward the blocking capacitor 25 charged negatively, and as illustrated with the arrow in FIG. 3B, the positive ions collide with the insulating layer 11 to generate a dangling bond in the surface of the insulating layer 11, so that the surface of the insulating layer 11 is activated. Further, similarly, the surface of the insulating layer 11 of the second substrate is also activated.

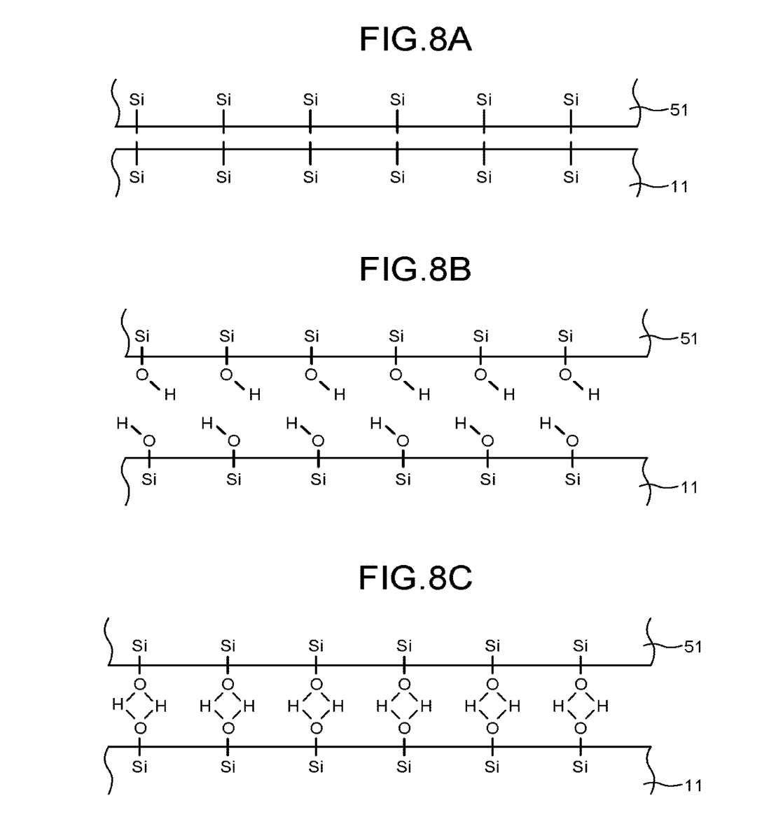

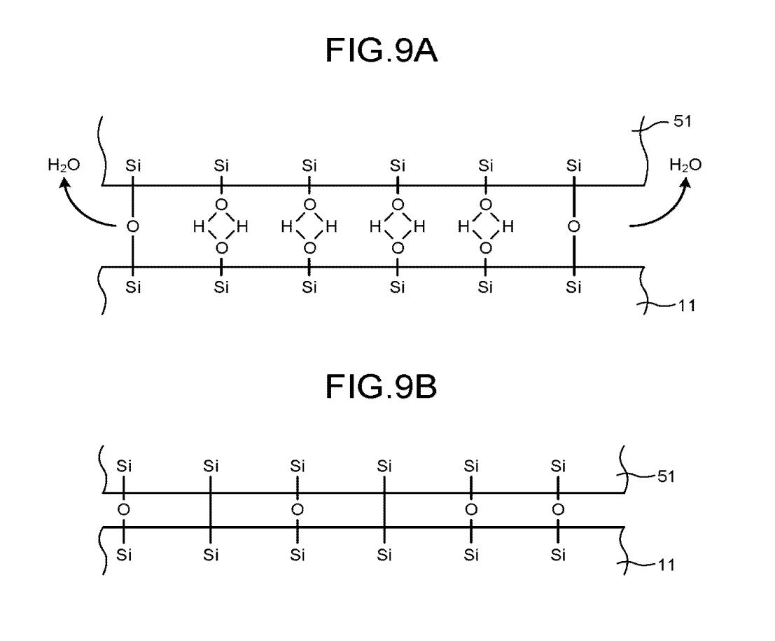

In this way, by activating both of the surface of the insulating layer 11 of the first substrate 10 and the surface of the insulating layer of the second substrate, the surface of the insulating layer 11 of the first substrate 10 and the insulating layer of the second substrate can be directly bonded in a firm manner without using an adhesive. The details of the direct bonding will be described below with reference to FIGS. 8A to 9B.

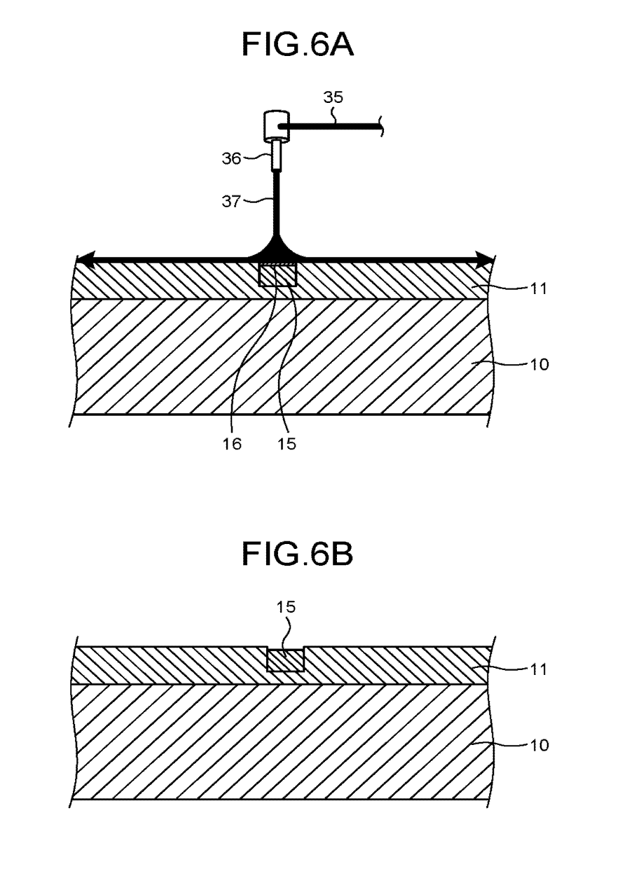

Next, the cleaning process performed after the activation of the surface of the insulating layer 11 will be described with reference to FIGS. 4 to 6B. FIG. 4 is a diagram for describing a cleaning apparatus according to the embodiment, and FIG. 5 is a Pourbaix diagram for copper. Further, the Pourbaix diagram for copper illustrates areas of copper in the water on a two-dimensional coordinate system of the potential of the (copper) electrode and pH. In addition, FIGS. 6A and 6B are diagrams for describing the cleaning procedure according to the embodiment.

Herein, the cleaning procedure of the first substrate 10 is the same as the cleaning procedure of the second substrate. Therefore, the description herein will be made about the cleaning procedure of the first substrate 10, and the cleaning procedure of the second substrate will not be given.

As illustrated in FIG. 4, a cleaning apparatus 31 includes a turntable 32, a driving unit 33, a cleaning solution supply unit 34, a pipe 35, and a discharge unit 36. The turntable 32 adsorbs and holds a substrate (herein, the first substrate 10) to be placed. The driving unit 33 drives the turntable 32 to be rotated. The cleaning solution supply unit 34 supplies a cleaning solution to the discharge unit 36 through the pipe 35. The discharge unit 36 discharges the cleaning solution toward the center of the turntable 32 as illustrated with the dotted arrow in FIG. 4.

Since the carbonated water is used as the cleaning solution, the cleaning apparatus 31 can remove the oxide film 16 from the surface of the electrode 15 without causing the surface of the insulating layer 11 to be roughened. Specifically, as illustrated in FIG. 5, when the copper having a copper oxide (Cu₂O) formed on the surface is dipped into the solution of 2 to 6 pH (acidity), the copper oxide (Cu₂O) becomes the copper (Cu), and the copper oxide (Cu₂O) disappears theoretically. In addition, though no voltage is applied to the solution in this embodiment, the copper oxide (Cu₂O) is more removed in a case where a negative voltage is applied.

Therefore, when the copper oxide film 16 formed in the surface of the electrode 15 is cleaned by the acid cleaning solution, a reductive reaction of the following formula (1) occurs.

Cu₂O+2H⁺+2e⁻→2Cu⁺+H₂O+2e⁻ (1)

In this way, the copper oxide film 16 becomes copper ions through the reductive reaction, and the copper ions are bonded again with the electrons to be copper and then removed by the cleaning. However, in a case where the cleaning solution has 2 to 3 pH (strong acid), the surface of the insulating layer 11 is roughened by the cleaning solution, and the bonding strength between the first substrate 10 and the second substrate may be lowered as described above.

Therefore, in this embodiment, the copper oxide film 16 formed in the surface of the electrode 15 is cleaned using the carbonated water which is adjusted to have 3.8 to 6 pH and preferably 4.5 pH. Specifically, as illustrated in FIG. 6A, in the cleaning procedure, carbonated water 37 is discharged from the discharge unit 36 toward the center of the surface of the insulating layer 11 while rotating the first substrate 10.

The carbonated water 37 supplied to the insulating layer 11 is widened by a centrifugal force of the first substrate 10 from the center of the surface of the insulating layer 11 toward the peripheral edge portion so as to be supplied to the entire surface of the insulating layer 11. Therefore, as illustrated in FIG. 6B, the cleaning apparatus 31 can remove the oxide film 16 from the surface of the electrode 15 regardless of the forming position of the electrode 15 in the insulating layer 11, and does not cause the surface of the insulating layer 11 to be roughened.

Further, since the oxide film 16 is removed, the surface of the electrode 15 is slightly retracted from the surface of the insulating layer 11, but will be thermally expanded by thermal treatment (described below) performed after the first substrate 10 and the second substrate are bonded. Therefore, the electrode 15 is connected to the electrode of the second substrate.

In addition, since the carbonated water 37 is used as the cleaning solution, the cleaning apparatus 31 can suppress particles from being attached to the surface of the insulating layer 11 compared to, for example, a typical cleaning apparatus which uses ultrapure water as the cleaning solution.

Specifically, in a case where the cleaning solution is supplied to the insulating layer 11 on the rotating first substrate 10, the surface of the insulating layer 11 is rubbed with the cleaning solution so as to cause static electricity and thus charged. Herein, the ultrapure water has a significantly high specific resistance of 18 MΩ·cm. Therefore, in a case where the cleaning is performed using the ultrapure water, the charged insulating layer 11 is not discharged, so that the particles may be attached to the insulating layer 11 by the static electricity.

On the contrary, for example, the carbonated water 37 having 3.8 to 6 pH has a specific resistance of 0.02 to 1.9 MΩ·cm which is significantly smaller than that of the ultrapure water. Therefore, in the cleaning apparatus 31, the carbonated water 37 having 3.8 to 6 pH, preferably 4.5 pH, and having a specific resistance of 0.02 to 1.9 MΩ·cm, preferably 0.1 MΩ·cm is used as the cleaning solution.

Therefore, in the cleaning apparatus 31, even when the static electricity is generated in the surface of the insulating layer 11 during the cleaning, the static electricity can be discharged through the carbonated water 37 having a significantly low specific resistance, so that it is possible to suppress the particles from being attached to the surface of the insulating layer 11.

In addition, in a case where a cleaning time is less than 1 second, the cleaning apparatus 31 is not able to control a discharge amount of the cleaning solution. In addition, when the cleaning time exceeds 120 seconds, the cleaning apparatus 31 may cause a reduction in throughput of the process. Therefore, the cleaning apparatus 31 continuously performs the cleaning with the carbonated water 37 on one substrate during 1 to 120 seconds, preferably 60 seconds.

Therefore, the cleaning apparatus 31 can sufficiently remove the oxide film 16 while keeping the throughput constant. Further, the cleaning apparatus 31 performs the cleaning process on the second substrate similarly to the first substrate 10.

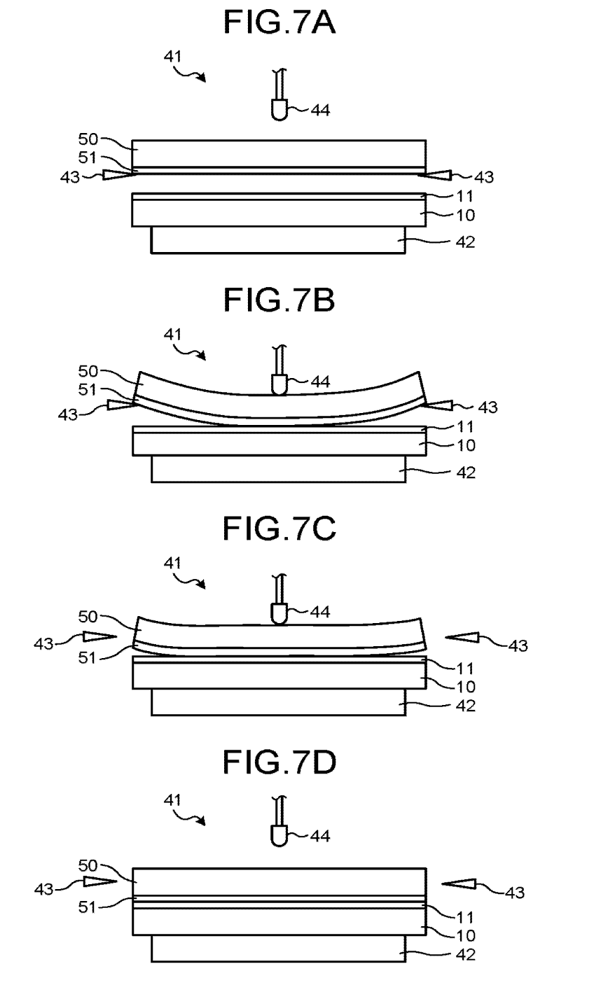

Next, a bonding procedure of the substrate will be described with reference to FIGS. 7A to 7D. FIGS. 7A to 7D are diagrams for describing the bonding procedure of the substrate according to the embodiment. Further, in FIGS. 7A to 7D, the components necessary for bonding the substrates are selectively illustrated among the components included in a bonding apparatus 41 for bonding the substrates.

The bonding procedure of the substrates is performed by the bonding apparatus 41 illustrated in FIGS. 7A to 7D. Specifically, the bonding apparatus 41 includes a stage 42, a support body 43, and a pressure element 44. The stage 42 adsorbs and holds the first substrate 10. The support body 43 is configured to be movable forward or backward in the horizontal direction, and supports a second substrate 50. The pressure element 44 is configured to be movable upward or downward, and presses the second substrate 50.

In a case where the first substrate 10 and the second substrate 50 are bonded by the bonding apparatus 41, first, the first substrate 10 is placed on the stage 42 while keeping the insulating layer 11 to face upward, and held by the stage 42 as illustrated in FIG. 7A.

Subsequently, the second substrate 50 already provided with the image sensor is placed while keeping an insulating layer 51 to face downward, and the peripheral edge portion of the surface (herein, the lower surface) of the insulating layer 51 is supported by the support body 43. At this time, for example, the vertical positions of the electrode 15 of the first substrate 10 and the electrode of the second substrate 50 are matched by matching the positions of an orientation flat and a notch of the first substrate 10 and the second substrate 50.

In addition, the vertical positions of the electrode 15 of the first substrate 10 and the electrode of the second substrate 50 may be matched by matching the pattern positions between the first substrate 10 and the second substrate 50. In this case, the support body 43 of the bonding apparatus 41 is desirably formed in the stage shape to adsorb and hold the second substrate 50 in order to correct the bending of the second substrate 50.

Thereafter, as illustrated in FIG. 7B, the pressure element 44 is lowered down, and the center position of the upper surface of the second substrate 50 is pressed by the pressure element 44. Therefore, the second substrate 50 is bent, and the center of the surface of the insulating layer 51 of the second substrate 50 and the center of the surface of the insulating layer 11 of the first substrate 10 are bonded.

Subsequently, as illustrated in FIG. 7C, the supporting of the second substrate 50 is released by retracting the support body 43. Therefore, the insulating layer 51 of the second substrate 50 and the insulating layer 11 of the first substrate 10 are widely bonded from the center to the peripheral edge portion.

Thereafter, finally, as illustrated in FIG. 7D, the entire surface of the insulating layer 51 of the second substrate 50 and the entire surface of the insulating layer 11 of the first substrate 10 are bonded. Then, the pressure element 44 is raised up, and the thermal treatment is performed, so that the bonding strength between the insulating layers 11 and 51 is increased and the bonding between the first substrate 10 and the second substrate 50 is completed. Through the thermal treatment, the electrode of the first substrate 10 and the electrode of the second substrate 50 are connected while being thermally expanded.

Next, the description will be made about the configuration for increasing the bonding strength between the insulating layers 11 and 51 through the thermal treatment performed on the first substrate 10 and the second substrate 50 which are bonded to each other with reference to FIGS. 8A to 9B. FIGS. 8A to 9B are diagrams for describing the configuration of the direct bonding of the substrates according to the embodiment.

As described above, when the surfaces of the insulating layers 11 and 51 are activated by the activation apparatus 21 illustrated in FIGS. 3A and 3B, the dangling bond is generated in silicon (Si) of the surfaces of the insulating layers 11 and 51 as illustrated in FIG. 8A. Then, when the surfaces of the insulating layers 11 and 51 are cleansed with the carbonated water 37 by the cleaning apparatus 31 illustrated in FIG. 4, the OH group is attached to the dangling bond of the silicon in the surfaces of the insulating layers 11 and 51 as illustrated in FIG. 8B.

Then, when the surfaces of the insulating layers 11 and 51 attached with the OH group are bonded, the OH group of the insulating layer 11 and the OH group of the insulating layer 51 are bonded by hydrogen as illustrated in FIG. 8C. Such a hydrogen bonding is a bonding caused by an intermolecular force. In this state, there is no sufficient bonding force between the insulating layers 11 and 51.

Thus, the thermal treatment is performed on the first substrate 10 and the second substrate 50 which are bonded through the hydrogen bonding. Therefore, as illustrated in FIG. 9A, the water (H₂O) is vaporized between the insulating layers 11 and 51. Finally, as illustrated in FIG. 9B, the silicon (Si) of the surfaces of the insulating layers 11 and 51 is bonded by a covalent bonding through oxygen (O). Therefore, the first substrate 10 and the second substrate 50 are directly bonded by a strong covalent bonding even without using an adhesive.

Thereafter, the first substrate 10 and the second substrate 50 bonded to each other are diced in a unit of chip, thereby manufacturing the semiconductor device having a two-stage chip. In the cleaning procedure during the manufacturing, the manufactured semiconductor device thus manufactured can suppress a connection failure and an increase of connection resistance between the electrodes since the oxide films 16 formed in the surface of the electrode 15 of the insulating layer 11 and the surface of the electrode of the insulating layer 51 are removed. Furthermore, in the cleaning procedure, a defect such as a bonding failure or a peeling between the insulating layers 11 and 51 can be suppressed since the surfaces of the insulating layers 11 and 51 are not roughened.

As described above, in the method of manufacturing the semiconductor device according to the embodiment, the electrodes are formed by a damascene method in the insulating layers provided in the surface of the first substrate and the surface of the second substrate, and then the surfaces of the insulating layers are activated by a plasma process.

Thereafter, the electrode and the surface of the insulating layer are cleaned using the carbonated water, and the insulating layer of the first substrate and the insulating layer of the second substrate are bonded to connect the electrode of the first substrate and the electrode of the second substrate.

According to the method of manufacturing the semiconductor device according to the embodiment, the metal oxide film can be removed from the surface of the electrode before the first substrate and the second substrate are bonded without causing the surface of the insulating layer to be roughened. Therefore, according to the method of manufacturing the semiconductor device according to the embodiment, it is possible to suppress the connection failure in the bonding portion of the electrodes connected by bonding the substrates.

Further, the above embodiment has been described about an example in a case where both of the first substrate and the second substrate are cleaned using the carbonated water. However, any one of the substrates may be cleaned using the carbonated water. The semiconductor device manufactured by bonding a pair of substrates of which any one is cleaned using the carbonated water can reduce the connection resistance of the electrode compared to the semiconductor device manufactured by bonding a pair of substrates which are not cleaned using the carbonated water.

In addition, the above embodiment has been described about a case where the substrate is cleaned using a single wafer cleaning apparatus. There may be used a cleaning apparatus in which a plurality of substrates are dipped into the carbonated water at a time and cleaned. Therefore, it is possible to increase the number of substrates to be cleaned in a unit time.

In addition, the above embodiment has been described in a case where the surface of the insulating layer and the surface of the electrode are cleaned using the carbonated water. However, at least the surface of the electrode is cleaned using the carbonated water, and a portion having no electrode may be cleaned using the pure water. Therefore, it is possible to reduce the using amount of the carbonated water.

In addition, this embodiment has been described about a case where two substrates are bonded, but this embodiment may be applied to a method of manufacturing the semiconductor device in which three or more substrates are bonded. In a case where three or more substrates are bonded, the electrode is formed in the insulating layer provided in the front and rear surfaces of each substrate, the surface of each insulating layer is activated, the insulating layers of the front and rear surfaces are cleaned using the carbonated water, and then the substrates are bonded to each other. Therefore, even in a case where three or more substrates are bonded, it is possible to suppress the connection failure between the electrodes to be connected by bonding.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
forming an opening in a surface of an insulating layer that is provided in a surface of a first substrate and a surface of a second substrate;
filling the opening with metal;
activating the surface of the insulating layer;
cleaning a surface of the metal filled in the opening of the first substrate using carbonated water; and
connecting the filled metal of the first substrate and the filled metal of the second substrate by bonding the insulating layer of the first substrate and the insulating layer of the second substrate.

2. The method of manufacturing the semiconductor device according to claim 1,
wherein the filled metal is an electrode.

3. The method of manufacturing the semiconductor device according to claim 1, further comprising:
cleaning the surface of the filled metal of the second substrate using the carbonated water.

4. The method of manufacturing the semiconductor device according to claim 1, further comprising:
cleaning the surface of the filled metal by supplying the carbonated water to the entire surface of the insulating layer where the filled metal is formed.

5. The method of manufacturing the semiconductor device according to claim 1,
wherein the carbonated water has 3.8 to 6.0 pH.

6. The method of manufacturing the semiconductor device according to claim 1,
wherein the carbonated water has a specific resistance of 0.02 [MΩ·cm] to 1.9 [MΩ·cm].

7. The method of manufacturing the semiconductor device according to claim 1,
wherein the cleaning of the surface of the filled metal of the first substrate using the carbonated water includes removing an oxide film from the surface of the filled metal.

8. The method of manufacturing the semiconductor device according to claim 3,
wherein the cleaning of the surface of the filled metal of the second substrate using the carbonated water includes removing an oxide film from the surface of the filled metal.

9. The method of manufacturing the semiconductor device according to claim 1,
wherein the cleaning of the surface of the filled metal of the first substrate using the carbonated water includes discharging static electricity generated in the first substrate through the carbonated water.

10. The method of manufacturing the semiconductor device according to claim 3,
wherein the cleaning of the surface of the filled metal of the second substrate using the carbonated water includes discharging static electricity generated in the second substrate through the carbonated water.

11. The method of manufacturing the semiconductor device according to claim 1,
wherein the cleaning of the surface of the filled metal of the first substrate using the carbonated water includes cleaning a sheet of the first substrate continuously using the carbonated water during 1 to 120 seconds.

12. The method of manufacturing the semiconductor device according to claim 3,
wherein the cleaning of the surface of the filled metal of the second substrate using the carbonated water includes cleaning a sheet of the second substrate continuously using the carbonated water during 1 to 120 seconds.

13. The method of manufacturing the semiconductor device according to claim 1,
wherein the cleaning of the surface of the filled metal of the first substrate using the carbonated water includes cleaning a plurality of the first substrates by dipping the first substrates into the carbonated water at a time.

14. The method of manufacturing the semiconductor device according to claim 3,
wherein the cleaning of the surface of the filled metal of the second substrate using the carbonated water includes cleaning a plurality of the second substrates by dipping the second substrates into the carbonated water at a time.

15. The method of manufacturing the semiconductor device according to claim 1,
wherein the connecting the filled metal of the first substrate and the filled metal of the second substrate includes connecting the filled metal of the first substrate and the filled metal of the second substrate by performing thermal treatment on the bonded first and second substrates and thermally expanding the filled metal of the first substrate and the filled metal of the second substrate.

16. The method of manufacturing the semiconductor device according to claim 1,
wherein the activating the surface of the insulating layer includes a plasma process that is performed on the surface of the insulating layer.

17. The method of manufacturing the semiconductor device according to claim 1,
wherein the first substrate is a substrate in which a logic circuit is formed, and
the second substrate is a substrate in which an image sensor is formed.
